(19) United States
(12) Patent Application Publication
(10) Pub. No.: US 2004/0246356 A1
(43) Pub. Date: Dec. 9, 2004

(54) Solid-state imaging device and method for driving the same

(76) Inventor: Eiji Koyama, Kyoto (JP)

Correspondence Address: Edwards & Angell, LLP, P. O. Box 55874, Boston, MA, 02205, US

(21) Appl. No.: 10/850,628

(22) Filed: May 21, 2004

(30) Foreign Application Priority Data
May 21, 2003 (JP) 2003-144127

(51) Int. Cl. H04N 5/335

(52) U.S. Cl. 348/308

(57) ABSTRACT

A solid-state imaging device includes at least one pixel cell for outputting a signal in correspondence with an amount of charges generated by opto-electric conversion; and a voltage generation circuit for generating a control voltage for outputting the signal from the at least one pixel cell. A part of the voltage generation circuit has an identical structure to that of a part of the at least one pixel cell.

This non-provisional application claims priority under 35 U.S.C., §119(a), on Patent Application No. 2003-144127 filed in Japan on May 21, 2003, the entire contents of which are hereby incorporated by reference.

### BACKGROUND OF THE INVENTION

1. Field of the Invention

The present invention relates to a solid-state imaging device using a threshold voltage modulation-system MOS-type image sensor or the like, which to usable for an image input device such as a video camera, an electronic camera, an image input camera, a scanner, a facsimile device or the likes and a method for driving the same.

2. Description of the Related Art

Conventionally, a semiconductor image sensor such as, for example, a CCD-type image sensor or a MOS-type image sensor is used for most image input devices. Recently, aMOS-type image sensor has again been attracting attention for the advantages of consuming less power than a CCD-type image sensor and for the ability to be produced with a CMOS technique which in also used for producing peripheral circuits.

With such a trend, Japanese Patent No. 2935492, for example, discloses a solid-state imaging device which uses an improved MOS-image sensor and includes a carrier pocket region (a high concentration buried layer) acting as a charge accumulation region below a channel region of a MOS transistor for detecting optical signals.

FIG. 7 is a plan view of one pixel call 20 of aMOS-type image sensor (solid-state imaging device) 10a. FIG. 8 is a cross-sectional view of the MOB-type image sensor 10a shown in FIG. 7 taken along line A-A in FIG. 7. The MOS-type image sensor 100a includes a plurality of pixel calls 20 (unit pixels) arranged two-dimensionally (for example, in a matrix).

As shown in FIGS. 7 and 8, each pixel cell 20 includes a light receiving diode 2L and a signal detection MOS transistor 22. The light receiving diode 21 generates charges by performing opto-electric conversion of incident light. The signal detection MOS transistor 22 is provided adjacent to the light receiving diode 21 and accumulates the charges output from the light receiving diode 21. The signal detection MOS transistor 22 outputs a signal in accordance with the amount of charges generated by the opto-electric conversion. The light receiving diode 21 and the signal detection MOS transistor 22 are connected to each other via a P-type well region 34 in an electrically floating state.

The light receiving diode 21 includes the P-type well region 34, surrounded by an N-type well region 32, for receiving light and generating charges. The light receiving diode 21 shares a drain region 33 as an N-type region with the signal detection MOB transistor 22. The drain region 33 is provided on a surface of the P-type well region 34. The light receiving diode 21 shares the P-type well region 34 with the signal detection MOS transistor 22.

The N-type well region 32 is provided so as to surround the P-type well region 34 and is connected to the drain region 33. A P⁺-type channel stop region 31 is provided below the N-type well region 32 and between two adjacent pixel cells 20. The N-type well region 32 is divided into a plurality of areas each corresponding to one pixel cell 20 by the P⁺-type channel stop region 31 and a P-type substrate 30 (FIG. 8). Thus, the plurality of pixel cells are formed.

The signal detection MOS transistor 22 includes the N⁺-type drain region 33, the P-type well region 34, an N⁺-type source region 35, a P⁺-type hole pocket region (charge accumulation region) 36, and a gate electrode 37.

The N⁺-type drain region 33 is formed on the surface of the P-type well region 34 so as to surround the gate electrode 37.

The N⁺-type source region 35 is formed on the surface of the P-type well region 34 and inside the gate electrode 37.

The P⁺-type hole pocket region 36 is formed at a position which is in the P-type well region 34, below the gate electrode 37 and in the vicinity of the source region 35. The P⁺-type hole pocket region 36 is provided so as to surround the source region 35. When seen from above, the N⁺-type hole pocket region 36 is ring-shaped.

The gate electrode 37 is provided on the P-type well region 34 with a gate insulating layer (not shown) interposed therebetween. The gate electrode 37 is also ring-shaped when seen from above.

A basic operation of the MOS-type image sensor 100a having the above-described structure will be described with reference to FIGS. 9A and 9B. FIGS. 9A and 9B show an example of the operation of the MOS-type image sensor 100a.

FIG. 9A is a timing diagram illustrating signal waveforms regarding a selected line, and FIG. 9B is a timing diagram illustrating signal waveforms regarding a non-selected line.

(Accumulation Period)

In an accumulation period, a drain voltage and a source voltage of the signal detection NOS transistor 22 are set to 1 V and a gate voltage of the signal detection MOS transistor 22 is set to about 3 V, regardless of whether the line connected to the signal detection MOS transistor 22 is a selected line or a non-selected line.

In the accumulation period, a light generation signal (charges) is generated in the P-type well region 34 of the light receiving diode 21. The P-type well region 34 is in a floating state. Since the hole pocket region 36 is a high impurity concentration region, the generated light generation signal is transferred from the P-type well region 34 and collected in the P⁺-type hole pocket region 36 by an electric field formed by a P-type concentration gradient.

At this point, the signal detection MOS transistor 22 is ON, and the drain region 33 and the source region 35 are completely conducting to each other. Therefore, an area immediately below the gate electrode 37 is filled with electrons. Accordingly, an area immediately below the drain region 33, the source region 35 and the gate is electrode 37 is entirely filled with electrons, which suppresses the generation of a dark current component at an interface of each transistor.

(S Read Period)

In a signal read period (S read period), the signal detection MOS transistor 22 connected to each selected line operates as followed. The source region 35 is connected to a constant current source which is common to all the signal detection MOS transistors in each column. A source follower circuit is formed including the drain region 33, the source region 35 and the gate electrode 37. As shown in FIG. 9A, the drain voltage is set to 3 V, and the gate voltage is set to about 2 V. With such settings, the signal detection MOS transistor 22 is operated in a saturated-state. Thus, the potential of the source region 35 is changed in accordance with the amount of charges (signal level) accumulated in the hole pocket region 36 (charge accumulation region), and is read as a signal.

The signal detection NOS transistor 22 connected to each non-selected line operates as follows. The source regions 35 of the pixel cells 20 arranged in a vertical direction are commonly connected. Therefore, as shown in FIG. 9B, all the gate voltages of each non-selected line are set to 0 V, so that the signal read operation of the non-selected line is in a cut-off state.

(Sweep-Out Period)

In a sweep-out period, the signal detection MOS transistor 22 connected to each selected line operates as follows. The drain region 33, the source region 35 and the gate electrode 37 are each supplied with a high voltage of about 5 V to 7 V. In this example, as shown in FIG. 9A, the drain voltage and the source voltage are each set to 5 V, and the gate voltage is set to 7 V. With such settings, all the charges accumulated in the hole pocket region 36 are swept out toward the P-type substrate 30.

The signal detection MOS transistor 22 connected to each non-selected line operates as follows. Again, the source regions 35 of the pixel cells 20 arranged in the vertical direction are commonly connected. Therefore, as shown in FIG. 9B, although the source region 35 is supplied with a high voltage of 5 V, all the gate voltages are set to 0 V like in the signal read period. Thus, the sweep-out operation of the non-selected line is in a cut-off state.

(N Read Period)

In a noise read period (N read period), the signal detection MOS transistor 22 connected to each selected line operates as follows. The source region 35 is Connected to a constant current source which is common to all the signal detection MOS transistors in each column, like in the signal read period. A source follower circuit is formed including the drain region 33, the source region 35 and the gate electrode 37. As shown in FIG. 9A, the drain voltage is set to 3 V, and the gate voltage is set to about 2 V. With such settings, the signal detection MOS transistor 22 is operated in a saturated state. Thus, a signal in the state where the hole pocket region 36 has no charges (no signal) accumulated therein is read.

The signal detection MOS transistor 22 connected to each non-selected line operates as follows. The source regions 35 of the pixel cells 20 arranged in the vertical direction are commonly connected. Therefore, as shown in FIG. 9B, all the gate voltages are set to 0 V, so that the noise read operation of the non-selected line is in a cut-off state, like in the signal read period.

Finally, a difference between the signal read in the signal read period (S output) and the signal read in the noise read period (N output) is output through a differential amplification circuit, a clamp circuit or the like. In this manner, the influence of variance of offsets among the signal detection MOS transistors 22 of the pixel cells 20 is reduced.

In the basic operation of the MOS-type image sensor 100a described above, the signal detection NOS transistor 22 acts as the source follower in the read periods (signal read period and the noise read period). FIG. 10 shows a circuit structure of one pixel cell 20 in this operation, together with the constant current source. FIG. 1, shows the relationship between the read voltage which is applied to the gate electrode (gate voltage) and the source voltage in this operation. In FIG. 11, the vertical axis represents the source voltage, and the horizontal axis represents the read voltage (gate voltage).

As shown in FIGS. 10 and 11, an the amount of light received by the light receiving diode 21 in increased (i.e., as the level of illumination is increased) and thus the amount of generated charges is increased, the threshold voltage of the signal detection MOS transistor 22 is decreased. Accordingly, as the amount of light received by the light receiving diode 21 to increased, the source voltage VS increases at the same gate voltage VG.

The degree of change in the source voltage VS is in proportion to the amount of generated charges. Thus, a signal in a bright period as shown in FIG. 11 (VS(1)-VS(0)) is read as a signal component. VS(1) represents the source voltage with respect to the gate voltage VG in the bright period, and VS(0) represents the source voltage with respect to the gate voltage VG in a dark period, both when a prescribed voltage is applied to the gate electrode.

FIG. 12 shows a potential profile of the MOS-type image sensor 100a described above. When the amount of light is so large (the level of illumination is so high) that the signal detection MOS transistor 22 is saturated as shown in FIG. 12, an excessively high level of light generation signal is accumulated as the signal charges in the hole pocket region 36 of the signal detection MOS transistor 22 (as represented by a hatched area in FIG. 12). As a result, the signal charges flow over the potential barrier provided by the N-type well region 32 toward the P-type substrate 30. In this case, the hole pocket region 36 becomes a saturated state in which no more signal charges can be accumulated therein.

FIG. 13 shows another potential profile of the MOS-type image sensor 100a described above. The potential profile shown in FIG. 13 is obtained when the gate voltage is increased. As shown in FIG. 13, as the gate voltage is increased, the potential barrier provided by the N-type well region 32 is decreased. As a result, the signal charges more easily flow toward the P-type substrate 30. Thus, the maximum amount of signal charges which can be accumulated in the hole pocket region 36 is reduced (as represented by a hatched area in FIG. 13).

In FIG. 11, when the level of illumination is so high that the pocket region 36 is saturated with the signal charges (high illumination), the gradient of the line representing the gate voltage VG with respect to the source voltage VS (VS(2)) is smaller than the gradient of the line representing the gate voltage VG in the bright period (VS(1)) or the line representing the gate voltage VG in the dark period (VS(0)). This occurs for the above-described reason.

In the above-described MOS-type image sensor 100a, the level of the gate voltage which is applied to the gate electrode 37 of the signal detection MOS transistor 22 in the read periods (signal read period and the noise read period) is determined as follows.

As described above, the source regions 35 of the pixel cells 20 arranged in a vertical direction are commonly connected. The level of the source voltage changes in accordance with the level of illumination in a positive potential direction (i.e., as the level of illumination increases, the level of the source voltage increases). Therefore, the source voltage VS of a selected line needs to be higher than the source voltage VS of a non-selected line. The reason is that when the source voltage VS of the selected line is lower than the source voltage VS of the non-selected line, the source voltage VS of the non-selected line is read.

Accordingly, the gate voltage VG needs to fulfill the condition of VS0(2)<VS(0) (see FIG. 11). VS0(2) represents the maximum source voltage (i.e., the source voltage at high illumination) of a non-selected line (the corresponding gate voltage is set to 0 V). VS(0) represents the minimum source voltage (i.e., the source voltage in the dark period) of a selected line.

However, when the gate voltage VG in the read periods is set to a very high level in order to fulfill this condition, the voltage of the saturated signal (VS(2)-VS(0)) becomes too small.

The characteristics of the signal detection MOS transistor 22 included in the pixel cell 20 are known to change also by variance in various production parameters and temperature changes.

The minimum gate voltage VG, at which the condition VS0(2)<VS(0) is constantly fulfilled even when the characteristics of the signal detection MOS transistor 22 change by variance in various production parameters and temperature changes, is set as the gate voltage in the read periods. Such a gate voltage is usually set to 2 V or less.

In the above-described MOS-type image sensor 100a, even when the characteristics of the signal detection MOS transistor 22 change by variance in various production parameters and temperature changes, the gate voltage VS applied to the signal detection MOS transistor 22 during the read periods is constantly set to the minimum gate voltage VG, at which the condition VS0(2)<VS(0) is fulfilled.

With reference to FIG. 14, it is assumed that the amount of light generation signal (signal charges) which can be accumulated in the hole pocket region 36 at the time of high illumination is changed to three amounts (VS0(2)max, VS0(2)typ, and VS0(2)min) by variance in various production parameters and temperature changes. Namely, it is assumed that the maximum source voltage VS0(2) is changed. In such a case, the gate voltage VG needs to be set so as to fulfill VS0(2)max<VS(0).

In the case where the change in the VS0(2) caused by variance in various production parameters and temperature changes is ±0.2 V with respect to VS0(2)typ (typical value), this change decreases the voltage of the saturated signal by 0.4 V at the maximum. This results in the deterioration of the S/N ratio of a video signal.

### SUMMARY OF THE INVENTION

According to one aspect of the invention, a solid-state imaging device includes at least one pixel cell for outputting a signal in correspondence with an amount of charges generated by opto-electric conversion; and a voltage generation circuit for generating a control voltage for outputting the signal from the at least one pixel cell. A part of the voltage generation circuit has an identical structure to that of a part of the at least one pixel call.

In one embodiment of the invention, the at least one pixel cell includes a first light receiving diode for generating charges by performing opto-electric conversion of incident light i and a first signal detection transistor including a charge accumulation region for accumulating charges which are output from the first light receiving diode.

In one embodiment of the invention, the control voltage is applied to the first signal detection transistor for reading the signal. The voltage generation circuit includes at least one second light receiving diode having an identical structure to that of the first light receiving diode and produced simultaneously with the first light receiving diode, and at least one second signal detection transistor having an identical structure to that of the first signal detection transistor and produced simultaneously with the first signal detection transistor.

In one embodiment of the invention, the voltage generation circuit includes a first cell and a second cell each including one of the at least one second light receiving diode and one of the at least one second signal detection transistor, and a differential amplification circuit for receiving an output voltage from each of the first cell and the second cell and thus outputting the control voltage. In one embodiment of the invention, the second signal detection transistor included in the first cell includes a first source region, a first gate electrode, and a first drain region. The second signal detection transistor included in the second cell includes a second source region, a second gate electrode, and a second drain region. For reading the signal, the first source region is connected to one of two inputs of the differential amplification circuit and a first constant current source, the first gate electrode is supplied with a ground voltage, and the first drain region is supplied with a first supply voltage. For reading the signal, the second source region is connected to the other of the two inputs of the differential amplification circuit and a second constant current source, the second gate electrode is connected to an output of the differential amplification circuit, and the second drain region is supplied with a second supply voltage.

In one embodiment of the invention, for reading the signal, the first cell is set to a state which is substantially the same as a state where a charge accumulation region included in the first cell is saturated with accumulated charges. For reading the signal, the second cell is set to a state which is substantially the same as a state where a charge accumulation region included in the second cell has no charges accumulated therein.

In one embodiment of the invention an offset value is added to at least one of the output voltage from the first cell and the output voltage from the second cell.

In one embodiment of the invention, a current value output by the first constant current source and a current value output by the second constant current source are different from each other.

In one embodiment of the invention, the at least one pixel cell, the first cell and the second cell each act as a source follower circuit for reading the signal.

According to another aspect of the invention, a method for driving a solid-state imaging device is provided. The solid-state imaging device includes at least one pixel cell for outputting a signal in correspondence with an amount of charges generated by opto-electric conversion; and a voltage generation circuit for generating a control voltage for outputting the signal from the at least one pixel cell. The at least one pixel cell includes a first light receiving diode for generating charges by performing opto-electric conversion of incident light; and a first signal detection transistor including a charge accumulation region for accumulating charges which are output from the first light receiving diode. The voltage generation circuit includes a first cell and a second cell each including a second light receiving diode having an identical structure to that of the first light receiving diode and produced simultaneously with the first light receiving diode, and a second signal detection transistor having an identical structure to that of the first signal detection transistor and produced simultaneously with the first signal detection transistor; and a differential amplification circuit for receiving an output voltage from each of the first cell and the second cell and thus outputting the control voltage. The method includes the step of, for reading the signal, applying a voltage having the same level as that of the voltage applied to a gate electrode included in a non-selected first signal detection transistor to a gate electrode included in the second signal detection transistor of the first cell.

In one embodiment of the invention, the method further includes the steps of before reading the signal, sweeping out charges accumulated in a charge accumulation region included in the second cell, thereby setting the second cell to a state which is substantially the same as a state where the charge accumulation region included in the second cell has no charges accumulated therein; and before reading the signal, refraining from sweeping out charges accumulated in a charge accumulation region included in the first call, thereby setting the first cell to a state which is substantially the same as a state where the charge accumulation region included in the first cell is saturated with accumulated charges.

In one embodiment of the invention, the method further includes the steps of before reading the signal, sweeping out charges accumulated in a charge accumulation region included in the second cell, thereby setting the second cell to a state which is substantially the same as a state where the charge accumulation region included in the second cell has no charges accumulated therein; and before reading the signal, refraining from sweeping out charges accumulated in a charge accumulation region included in the first call, and injecting charges into the charge accumulation region included in the first cell, thereby setting the first call to a state which is substantially the same as a state where the charge accumulation region included in the first cell is saturated with accumulated charges.

In one embodiment of the invention, the method further includes the step of, for reading the signal, applying the control voltage to a gate electrode included in the first signal detection transistor.

According to the present invention, a part of the voltage generation circuit has an identical structure to that of a part of the pixel cell. More specifically, the voltage generation circuit includes a second light receiving diode having an identical structure to that of, and produced simultaneously with, a first light receiving diode of the pixel cell; and a second signal detection MOS transistor having an identical structure to that of, and produced simultaneously with, a first signal detection MOS transistor of the pixel cell. Owing to such a structure, when a characteristic of each pixel cell changes substantially the same change occurs in the voltage generation circuit. Therefore, the voltage generation circuit can generate an optimum control voltage in compliance with the characteristic change of the pixel cell, and apply such an optimum control voltage to the pixel call.

The voltage generation circuit includes a first cell and a second cell each including a second light receiving diode and a second signal detection MOS transistor, and a differential amplification circuit for receiving an output voltage from each of the first call and the second cell and thus outputting a control voltage.

The second signal detection MOS transistor included in the first cell includes a first source region, a first gate electrode, and a first drain region. The second signal detection MOS transistor included in the second cell includes a second source region, a second gate electrode, and a second drain region. For reading a signal, the first source region is connected to one of two inputs of the differential amplification circuit (for example, a positive input) and a first constant current source; the first gate electrode is supplied with a ground voltage; and the first drain region is supplied with a first supply voltage.

For reading the signal, the second source region is connected to the other of the two inputs of the differential amplification circuit (for example, a negative input) and a second constant current source; the second gate electrode is connected to an output of the differential amplification circuit; and the second drain region is supplied with a second supply voltage.

Before reading the signal, the charges accumulated in a charge accumulation region included in the second cell are swept out, so that the second cell in set to a state which is substantially the same as a state where the charge accumulation region included in the second cell has no charges accumulated therein (dark period state). Before reading the signal, the charges accumulated in a charge accumulation region included in the first cell are not swept out, so that the first cell is set to a state which is substantially the same as a state where the charge accumulation region included in the first cell is saturated with accumulated charges (high illumination state). Before reading a signal, the charges are injected into the charge accumulation region included in the first cell, so that the first cell is set, with certainty, to a state which is substantially the same as a state where the charge accumulation region included in the first cell is saturated with accumulated charges (high illumination state).

For reading a signal from each pixel, a voltage having the same level as that of the voltage applied to the gate electrode included in the first signal detection is translator in a non-selected state (i.e., 0 V or ground voltage) is applied to the gate electrode included in the second signal detection transistor of the first cell. With such an application, the differential amplification circuit can output a control voltage which fulfills the conditions of: the maximum source voltage (source voltage at high illumination) of a non-selected line (VS0(2))=the minimum source voltage (source voltage in the dark period) of a selected line (VS(0)).

An offset value is added to at least one of the output voltage from the first call and the output voltage from the second cell. Alternatively, a current value which is output by the first constant current source and a current value which is output by the second constant current source are set to bed different from each other. With such a setting, the differential amplification circuit can output a control voltage which fulfills the conditions of: the maximum source voltage (source voltage at high illumination) of a non-selected line (VS0(2))<the minimum source voltage (source voltage in the dark period) of a selected line (VS(0)).

For reading a signal from each pixel cell, a control voltage which is output by the differential amplification circuit is applied to the gate electrode of the first signal detection MOS transistor of each pixel. With such an application, even when a characteristic of each pixel cell changes due to the variance in various production parameters and temperature changes, a control voltage in compliance with the characteristic change of the pixel cell 15 applied to the gate electrode. Therefore, the deterioration of the S/N ratio of the detection signal (video signal) is suppressed.

Thus, the invention described herein makes possible the advantages of providing a solid-state imaging device for suppressing the voltage of a saturated signal from deteriorating due to the changes in the characteristics caused by, for example, variance in various production parameters and temperature changes; and a method for driving the same.

These and other advantages of the present invention will become apparent to those skilled in the art upon reading and understanding the following detailed description with reference to the accompanying figures.

### BRIEF DESCRIPTION OF THE DRAWINGS

FIG. 1 shows a solid-state imaging device according to a first example of the present invention;

FIG. 2A is a timing diagram illustrating signal waveforms regarding an operation of a first cell of a voltage generation circuit shown in FIG. 1, which represents high illumination characteristics;

FIG. 2B is a timing diagram illustrating signal waveforms regarding an operation of a second cell of the voltage generation circuit shown in FIG. 1, which represents dark period characteristics;

FIG. 3 is a graph illustrating the relationship between a gate voltage (read voltage) and the source voltage generated by the voltage generation circuit shown in FIG. 1;

FIG. 4 is a circuit diagram illustrating a voltage generation circuit of a solid-state imaging device according to a second example of the present invention;

FIGS. 5A is a timing diagram illustrating signal waveforms regarding an operation of a first cell of a voltage generation circuit according to a third example of a present invention, which represents high illumination characteristics;

FIGS. 5B is a timing diagram illustrating signal waveforms regarding an operation of a second cell of the voltage generation circuit according to the third example of the present invention, which represents dark period characteristics;

FIG. 6A is a circuit diagram of a clamp circuit used in the third example according to the present invention;

FIG. 6D shows a timing diagram illustrating signal waveforms regarding an operation of the clamp circuit;

FIG. 7 is a partial plan View of a MOS-type image sensor in correspondence with one pixel call;

FIG. 8 is a cross-sectional view of the MOS-type image sensor shown in FIG. 7 taken along line A-A in FIG. 7:

FIG. 9A in an operation timing diagram of a selected line illustrating a basic operation of the MOS-type image sensor shown in FIGS. 7 and 8:

FIG. 9B is an operation timing diagram of a non-selected line illustrating the basic operation of the MOS-type image sensor shown in FIGS. 7 and 8;

FIG. 10 is a circuit diagram of a source follower circuit formed for reading a signal in a pixel cell of the MOS-type image sensor shown in FIGS. 7 and 8;

FIG. 11 to a graph illustrating the gate voltage vs. source voltage characteristics of the MOS-type image sensor shown in FIGS. 7 and 8;

FIG. 12 is a graph illustrating a potential profile of the MOS-type image sensor shown in FIGS. 7 and 8 when a charge accumulation region is saturated;

FIG. 13 is a graph illustrating a potential profile of the MOS-type image sensor shown in FIGS. 7 and 8 when a gate voltage is increased; and

FIG. 14 is a graph illustrating saturated signals in the MOS-type image sensor shown in FIGS. 7 and 8.

### DESCRIPTION OF THE PREFERRED EMBODIMENTS

Hereinafter, the present invention will be described by way of illustrative examples with reference to the accompanying drawings.

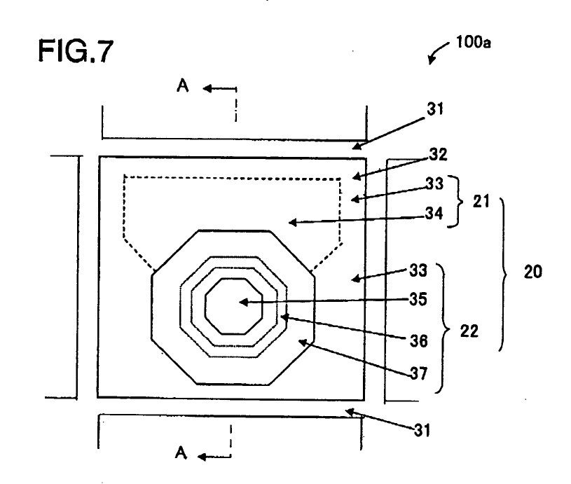

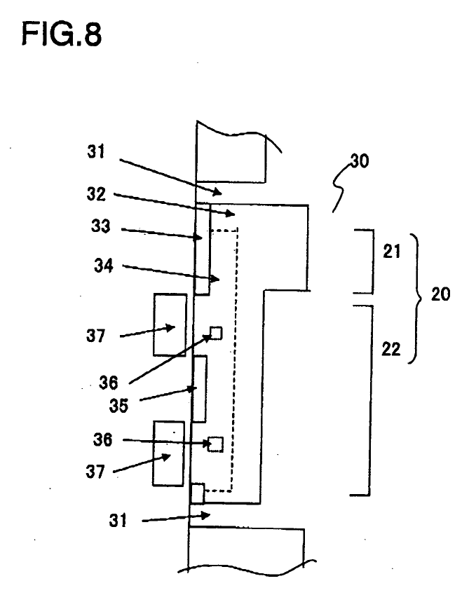

In first through third examples, a solid-state imaging device 100 according to the present invention is realized as a MOS-type image sensor including a plurality of pixel cells 20 located two-dimensionally (e.g., in a matrix). Each pixel cell 20 includes a light receiving diode 21 and a signal detection MOS transistor 22 as shown in FIGS. 7 and 8. Identical elements described above with reference to FIGS. 7 and 8 bear identical reference numerals thereto, and detailed descriptions thereof will be omitted.

### EXAMPLE 1

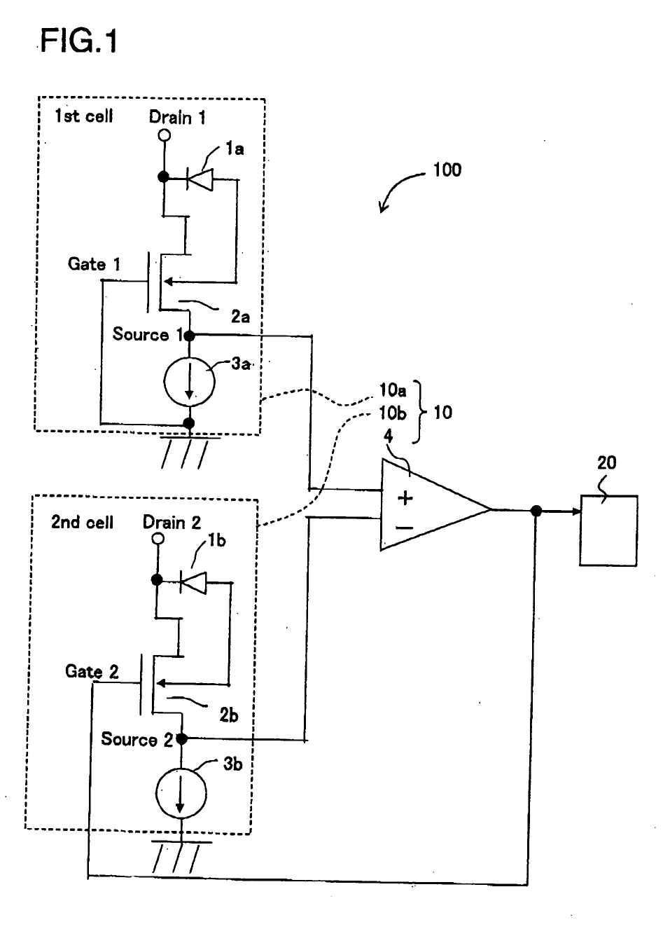

FIG. 1 shows a solid-state imaging device 100 according to a first example of the present invention. The solid-state imaging device 100 includes a voltage generation circuit 10 and at least one pixel cell 20. In this example, the solid-state imaging device 100 includes a plurality of the pixel cells 20.

As shown in FIG. 1, the voltage generation circuit 10 includes a first cell 10a including a light receiving diode 1a, a signal detection MOS transistor 2a, and a constant current source 3a; a second cell 10b including a light receiving diode 1b, a signal detection MOS transistor 2b, and a constant current source 3b; and a differential amplification circuit (operation amplifier) 4. The voltage generation circuit 10 is used for generating a control voltage (read voltage) which is applied to a gate electrode of a signal detection MOS transistor 22 of a pixel cell 20 for reading a signal by the signal detection MOS transistor 22.

The light receiving diodes 1a and 1b have the same structure as that of the light receiving diode 21 shown in FIGS. 7 and 8 and are produced simultaneously with the light receiving diode 21. The MOS transistors 2a and 2b have the same structure as that of the signal detection MOS transistor 22 shown in FIGS. 7 and 8 and are produced simultaneously with the signal detection MOS transistor 22. The characteristics of the first cell 10a and the second cell 10b are changed by variance in various production parameters and temperature changes, like in the pixel cell 20.

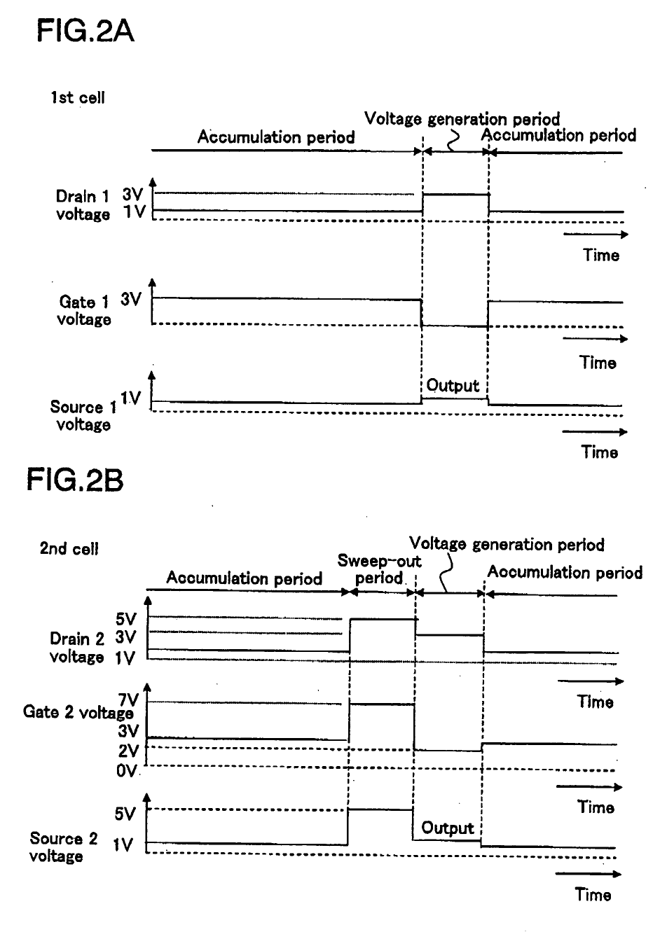

The first cell 10a has the following structure. First, the structure of the MOS transistor 2a will be described. A source region (source 1) is branched into two, one of which is connected to a positive input of the differential amplification circuit 4 and the other of which is connected to an input of the constant current source 3a. A gate electrode (gate 1) is connected to a ground voltage (in a voltage generation period in a signal read period; the gate electrode is supplied with 3 V in an accumulation period as shown in FIG. 2A). A drain region (drain 1) is connected to an output of a supply voltage. An N⁺ region of the light receiving diode 1a is connected to the drain region of the NOS transistor 2a, and a P-type well region of the light receiving diode 1a is connected to (i.e., integrated with) a P-type well region of the MOS transistor 2a.

The second cell lob has the following structure. First, the structure of the MOS transistor 2b will be described. A source region (source 2) is branched into two, one of which is connected to a negative input of the differential amplification circuit 4 and the other of which is connected to an input of the constant current source 3b. A gate electrode (gate 2) is connected to an output of the differential amplification circuit 4. A drain region (drain 2) is connected to an output of the supply voltage. An N⁺ region of the light receiving diode 1b is connected to the drain region of the MOS transistor 2b, and a P-type well region of the light receiving diode 1b is connected to (i.e., integrated with) a P-type well region of the MOS transistor 2b.

In the first cell 10a, the signal charges (for example, holes) are accumulated in a hole pocket region (charge accumulation region) to a maximum possible degree. The first cell 10a is operated in a saturated state in which the hole pocket region is overflown with the signal charges or an equivalent state thereto. The first cell 10a exhibits high illumination characteristics.

The second cell 10b is operated in a state where the hole pocket region has no charges accumulated therein (depleted state) or an equivalent state thereto. The second cell 10b exhibits dark period characteristics.

As described above, in the first cell 10a, the drain region of the MOS transistor 2a is connected to the output of the supply voltage, and the source region of the MOS transistor 2a is connected to the constant current source 3a. In the second cell 10b, the drain region of the MOS transistor 2b is also connected to the output of the supply voltage, and source region of the MOS transistor 2b is connected to the constant current source 3b. With such connections, for reading a signal, the MOS transistors 2a and 2b each act as a source follower circuit. The constant current sources 3a and 3b are formed of transistors or circuit portions thereof (not shown) which have the same size and produced by the same process. The constant current sources 3a and 3b are set to generate an identical amount of current.

In the voltage generation circuit 10, the gate voltage of the MOS transistor 2a included in the first cell 10a is set to 0 V like the gate voltage of a non-selected line, so that a negative feedback loop is formed. Owing to such a setting, a gate voltage which fulfills the condition that the maximum source voltage (at high illumination) of anon-selected line (VS0(2)) the minimum source voltage (in the dark period) of a selected line (VS(0) ) can be output from the differential amplification circuit 4 as a control voltage regardless of variance in various production parameters and temperature changes.

A conventional resistance division section or the like is connected between the source 2 and the ground voltage and thus an offset value is added to the potential to the source 2 to decrease the potential of the source 2. The decreased potential of the source 2 is supplied to the differential amplification circuit 4. Alternatively, the conventional resistance division section or the like is connected between the source 1 and the supply voltage and thus an offset value is added to the potential to the source 1 to increase the potential of the source 1. The increased potential of the source 1 is supplied to the differential amplification circuit 4. Using one of the above techniques the voltage which is output from the differential amplification circuit 4 can be easily set slightly higher. Thus, a gate voltage fulfilling the condition of VS0(2)<VS(0) can be easily output from the differential amplification circuit 4.

A method for driving the voltage generation circuit 10 having the above-described structure will be described with reference to FIGS. 2A and 2B.

FIG. 2A is a timing diagram illustrating signal waveforms regarding an operation of the first cell 10a representing the high illumination characteristics, and FIG. 2B is a timing diagram illustrating signal waveforms regarding an operation of the second cell 10b representing the dark period characteristics.

(Accumulation Period)

As shown in FIGS. 2A and 2B, in an accumulation period, the drain voltage and the source voltage are both set to 1 V and the gate voltage is set to about 3 V in the first cell 10a and the second cell 10b, like in the pixel cell 20 shown in FIGS. 7 and 8.

In the accumulation period, a light generation signal (charges) is generated in the P-type well region of each of the light receiving diodes 1a and 1b. The P-type well regions are in a floating state. Since the hole pocket region is a high impurity concentration region, the generated light generation signal is transferred from the P-type well region and collected in the P⁺-type hole pocket region by an electrical field formed by a P-type concentration gradient.

At this point, the MOS transistors 2a and 2b are ON, and the drain region and the source region are completely conducting to each other in each transistor. Therefore, an area immediately below the gate electrode is filled with electrons in each transistor. Accordingly, an area immediately below the drain region, the source region and the gate electrode is entirely filled with electrons, which suppresses the generation of a last current component at an interface of each transistor.

(Sweep-Out Period)

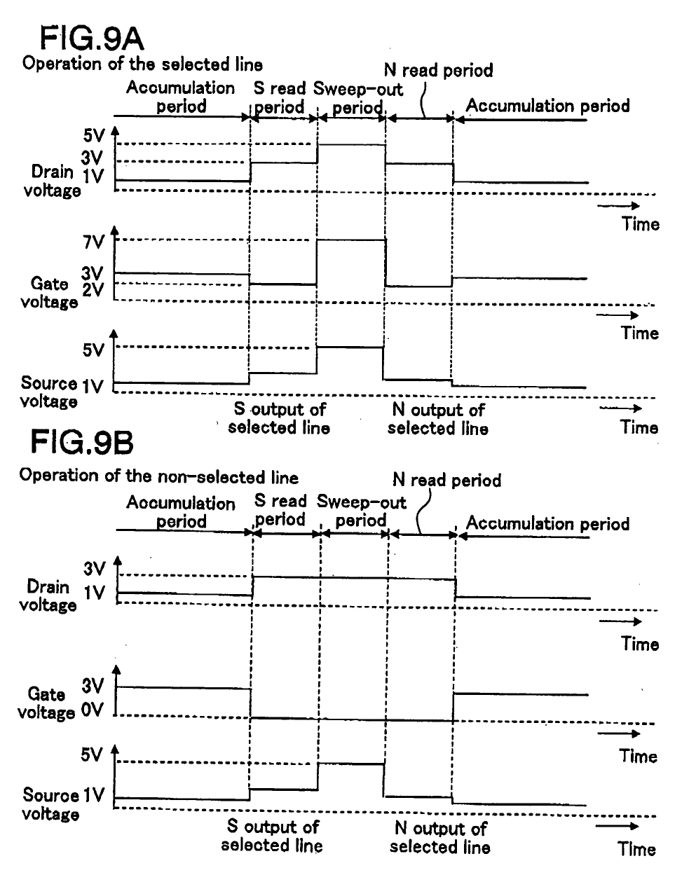

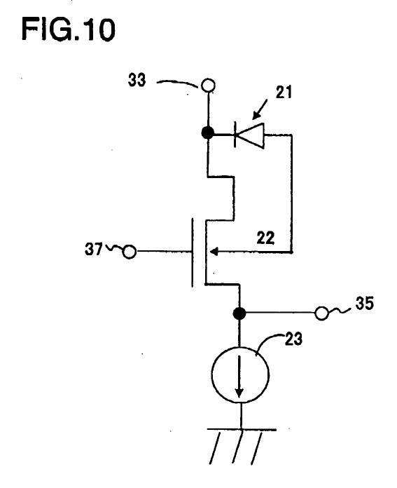

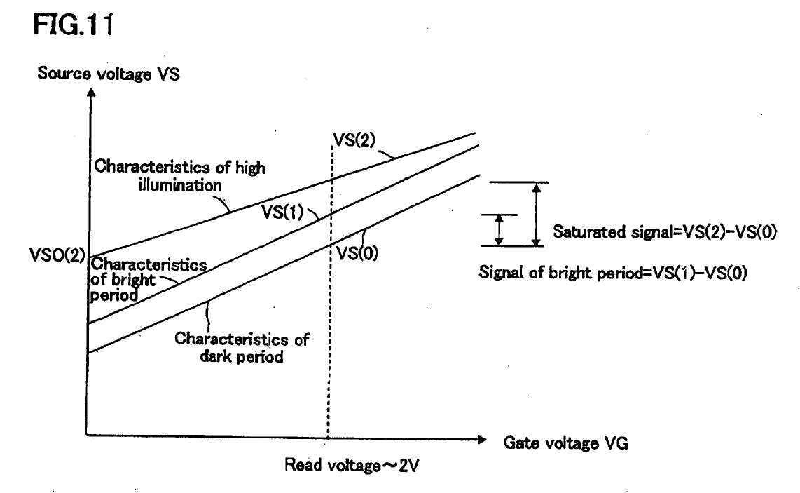

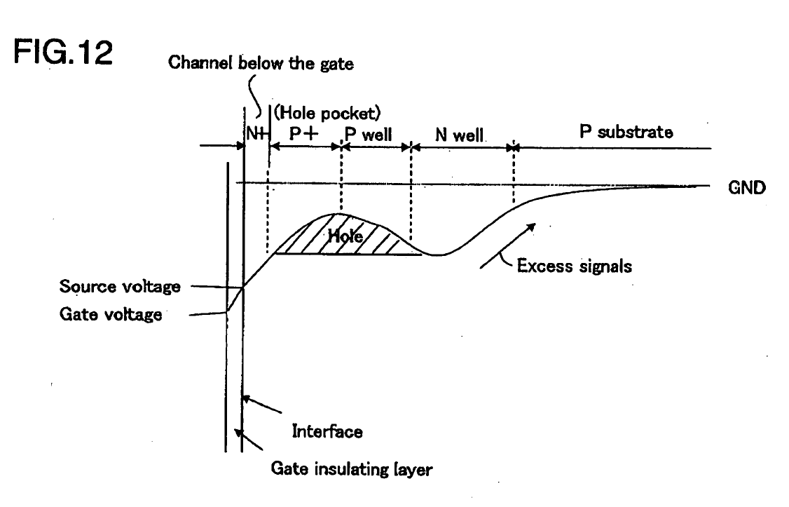

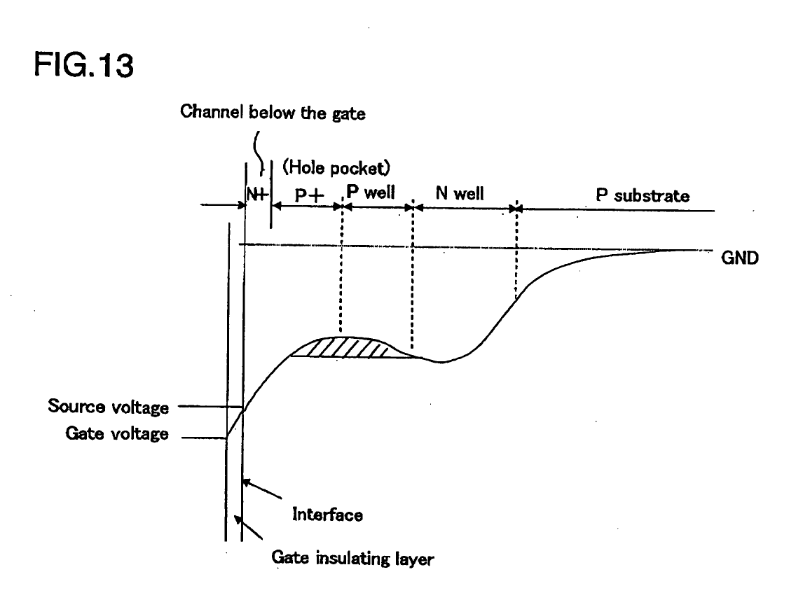

In a sweep-out period, the second cell 10b operates as follows. The drain region and the source region of the MOS transistor 2b are each supplied with a high voltage of 5 V, and the gate electrode of the MOS transistor 2b is supplied with a high voltage of about 7 V, like with the selected line in pixel cell 20 shown in FIG. 9A. With such settings, all the charges accumulated in the hole pocket region are swept out toward a P-type substrate. The second cell 10b is operated in a state in which the hole pocket region has no charges accumulated therein or an equivalent state thereto. The second cell 10b exhibits dark period characteristics.

With the first cell 10a, no sweep-out period is provided, and charges are accumulated in the hole pocket region 36 of the MOS transistor 2a. As a result, the signal charges are accumulated in the hole pocket region to a maximum possible degree. The first cell 10a is operated in a saturated state in which the hole pocket region is overflown with the signal charges or an equivalent state thereto. The first cell 10a exhibits high illumination characteristics.

(Voltage Generation Period)

In a voltage generation period (signal read period) subsequent to the sweep-out period, the gate electrode of the MOS transistor 2a in the first cell 10a is supplied with 0 V (i.e., a voltage having the same level as that of a voltage which is applied to the gate electrode included in the signal detection MOS transistor is connected to a non-selected line). Thus, a negative feedback loop is formed. Owing to such a setting, a gate voltage which fulfills the condition of VS0(2)=VS(0) can be output from the differential amplification circuit 4 as a control voltage, regardless of variance in various production parameters and temperature changes.

An offset value is added to an input voltage to the differential amplification circuit 4, so that the voltage which is output from the differential amplification circuit 4 is set slightly higher. Thus, a gate voltage which fulfills the condition of VS0(2)<VS(0) can be easily output from the differential amplification circuit 4.

The operations in the accumulation period and the sweep-out period shown in FIGS. 2A and 2B are performed only once at the time of starting the MOS-type image sensor 100. By performing the operations once, a gate voltage which accommodates a characteristic change of the pixel cell 20 can be generated. These operations may be performed in a vertical blanking interval of each frame. In such a case, even when a characteristic of the signal detection MOS transistor 22 changes due to temperature changes or the like during the operation of the MOS-type image sensor 100, a gate voltage in compliance with such a change can be generated.

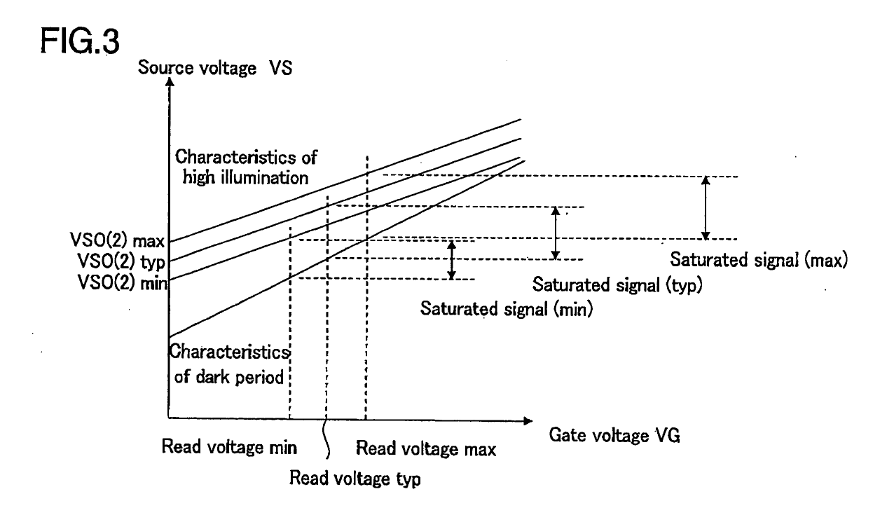

FIG. 3 shows the relationship between the gate voltage (i.e., read voltage) and the source voltage generated by the voltage generation circuit 10 (FIG. 1). In FIG. 3, the vertical axis represents the source voltage, and the horizontal axis represents the read voltage (gate voltage) applied to the pixel cell 20 for reading the signal.

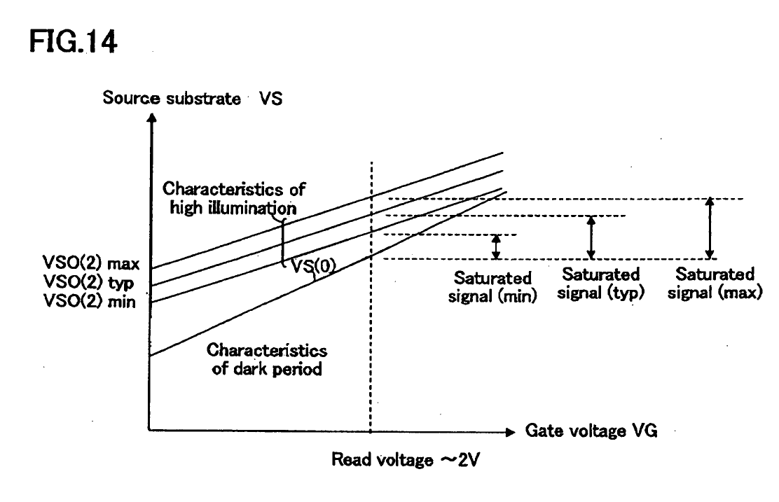

As shown in FIG. 3, as the maximum source voltage (source voltage at high illumination) of a non-selected line (VS0(2)) (the gate electrode of a MOS transistor connected to a non-selected line is supplied with 0 V) changes from VS0(2)min to VS0(2)typ, and to VS0(2)max, the read voltage also changes from min, to typ to max. Since the gate voltage which fulfills the condition of VS0(2)=VS(0) or the condition of VS0(2)<VS(0) is generated by the voltage generation circuit 10, the degree of decrease of the voltages of the saturated signal (typ) and the saturated signal (min) is lower in FIG. 3 than in FIG. 14 although the level of voltage of the saturated signal (max) is the same in FIG. 3 and FIG. 14.

It is assumed that, for example, VS0(2) changes by ±0.2 V, the gradient of each of the source voltage and the gate voltage in the dark period (FIGS. 3 and 14) is 0.9, and the gradient of each of the source voltage and the gate voltage at high illumination (FIGS. 3 and 14) is 0.5. In FIG. 14, the degree of decrease of the saturated signal is 0.4 V, whereas in FIG. 3, the degree of decrease of the saturated signal to 0.4×(0.5/0.9)−0.22 V. According to the present invention, the decrease of the saturated signal due to variance in various production parameters and temperature changes can be significantly reduced.

### EXAMPLE 2

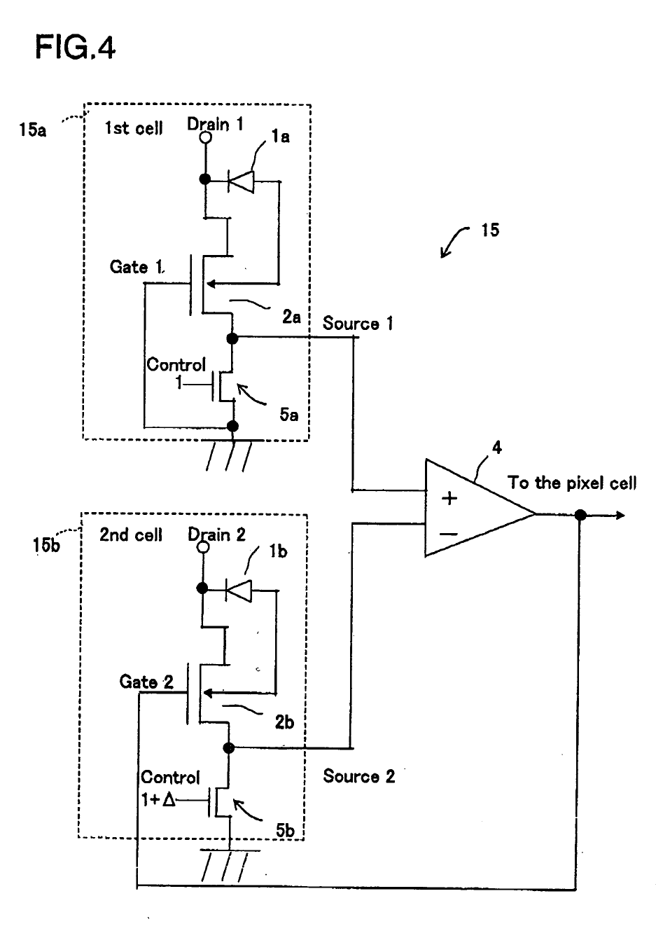

FIG. 4 is a circuit diagram illustrating a voltage generation circuit 15 of a solid-state imaging device according to a second example of the present invention. The voltage generation circuit 15 is a modification of the voltage generation circuit 10.

As shown in FIG. 4, the voltage generation circuit 15 includes a first cell 15a including a light receiving diode 1a, a signal detection MOS transistor 2a, and a constant current generation transistor 5a, a second cell 15b including a light receiving diode 1b, a signal detection MOS transistor 5b ; and a constant current generation transistor 2b, and a differential amplification circuit (operation amplifier) 4 for receiving an output from each of the first cell 15a and the second cell 15b.

Exemplary features of the voltage generation circuit 15 will now be described.

In the voltage generation circuit 10 shown in FIG. 1, the constant current source 3a and 3b forming the source follower circuits are formed of transistors or portions thereof (not shown) which have the same size and produced by the same process. The constant current source 3a and 3b are set to generate an identical amount of current.

By contrast, in the voltage generation circuit 15, a gate electrode of the transistor 5b, which is connected to the MOS transistor 2b of the second cell 15b, is supplied with a voltage higher by a prescribed level Δ than the voltage applied to the gate electrode of the transistor 5a, which is connected to the MOS transistor 2a of the first cell 15a. Namely, the gate electrode of the transistor 5b is supplied with the voltage of control 1+Δ. With such a setting, a slightly higher level of current flows in the transistor 5b than in the transistor 5a. Oppositely, the voltage generation circuit 15 may be structured such that a slightly lower level of current flows in the transistor 5b than in the transistor 5a.

By causing a slightly higher level of current to flow in the transistor 5b than in the transistor 5a, the source voltage of source 2 of the second cell 15b is decreased by a desired level, and a gate voltage which is higher by that level is output from the differential amplification circuit 4.

By using the read voltage which is output from the differential amplification circuit 4 as a gate voltage to be applied to the gate electrode 37 of the signal detection MOS transistor 22 for reading the signal from the pixel cell 20, the condition of VS0(2)<VS(0) can be fulfilled.

By adjusting the prescribed level Δ of the voltage in a positive direction, the value by which VS(0) is higher than VS0(2) can be controlled to be a desired level.

### EXAMPLE 3

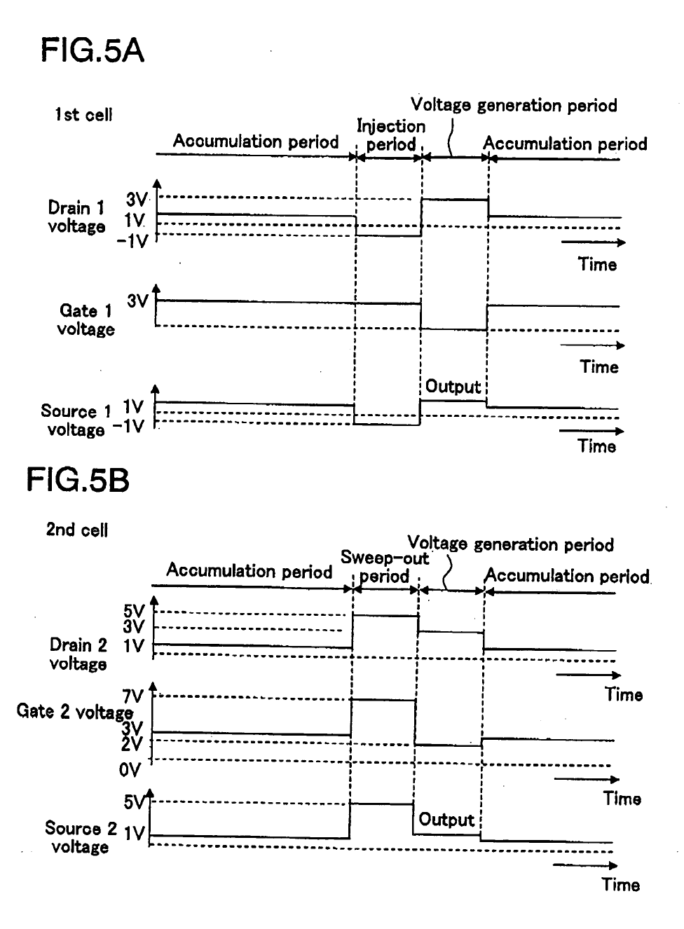

With reference to FIGS. 5A and 5B, a method for driving a voltage generation circuit according to a third example of the present invention will be described. FIG. 5A is a timing diagram illustrating signal waveforms regarding an operation of the first cell 15a representing the high illumination characteristics, and FIG. 5B is a timing diagram illustrating signal waveforms regarding an operation of the second cell 15b representing the dark period characteristics.

In the voltage generation circuit 10 shown in FIG. 1, the signal charges need to be sufficiently accumulated in the hole pocket region in order to allow the first cell 10a to exhibit the high illumination characteristics. In order to realize this, charges are accumulated without sweeping the charges.

By contrast, in this example, an infection period is provided for injecting signal charges to the hole pocket region of the first cell 15a.

In the second cell 15b, the signal charges are swept out like in FIG. 2B, prior to the voltage generation period. In the first cell 15a, in the sweep-out period, the drain region and the source region are each temporarily supplied with a negative voltage of −1 V; namely, charges are injected. This lowers the barrier of the N-type well region in the first cell 15a, and thus a sufficient amount of holes are injected from the P-type substrate to the hole pocket region in the P-type well region which to in a floating state. As a result, the first cell 15a exhibits high illumination characteristics. The method of the third example is applicable to the first cell 10a and the second cell 10b.

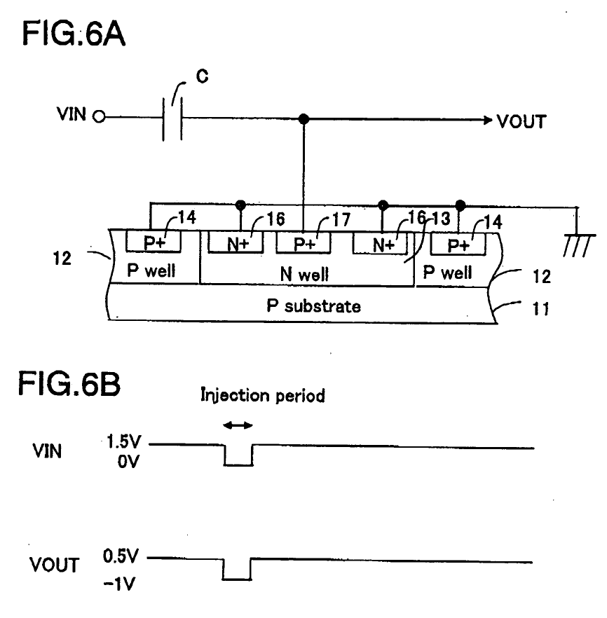

In the third example, the negative voltage applied to the source region and the drain region can be easily generated using a clump circuit shown in FIG. 6A.

As shown in FIG. 6A, the clamp circuit has a capacitance C. An input VIN is connected to a P⁺ region 17 via the capacitance C.

The clamp circuit has the following structure in the cross-section as shown in FIG. 6A. On a P-type substrate 11, an N-type well region 13 is provided, which is interposed between. P-type well regions 12. In each P-type well region 12, a P⁺ region (not shown), an N⁺ region (not shown) and a P⁺ region 14 are provided in an isolated state. In N-type well region 13, N⁺ regions 16 and a P⁺ region 17 are provided in an isolated state. The P⁺ region 14 and the N⁺ region 16 are electrically connected to each other and grounded.

As shown in FIG. 6B, a voltage of 0 V is applied to the input VIN during the charge injection period, so that a voltage of −1 V is output from an output VOUT. In the other periods, a voltage of 1.5 V is applied to the input VIN, so that a voltage of 0.5 V is output from the output VOUT. In this example, the drop voltage of the light receiving diode is 0.5 V.

In the above-described examples, the solid-state imaging device 100 includes a plurality of pixel cells 20. Each pixel cell 20 includes a light receiving diode 21 and a signal detection MOS transistor 22. The voltage generation circuit 10 (or 15) generates a control voltage which is applied to the pixel cell 20 for reading a signal. The voltage generation circuit 10 (or 15) includes a first cell 10a (or 15a) (also referred to as a “high illumination characteristic cell”), a second cell 10b (or 15b) (also referred to as a “dark period characteristic call”), and a differential amplification circuit 4. The high illumination characteristic cell 10a (or 15a) includes a light receiving diode 1a and a signal detection MOS transistor 2a. The dark period characteristic cell 10b (or 15b) includes a light receiving diode 1b and a signal detection MOS transistor 2b. The differential amplification circuit 4 is an operational amplifier for receiving a voltage which is output from each of the high illumination characteristic cell 10a (or 15a) and the dark period characteristic cell 10b (or 15b).

The voltage generation circuit 10 (or 15) includes the light receiving diodes 1a and 1b and the signal detection MOS transistors 2a and 2b. The light receiving diodes 1a and 1b have an identical structure to that of the light receiving diode 21 and are produced simultaneously with the light receiving diode 21. The signal detection MOS transistors 2a and 2b have an identical structure to that of the signal detection MOS transistor 22 and are produced simultaneously with the signal detection MOS transistor 22. Owing to such a structure, when a characteristic of each pixel cell 20 changes, substantially the same change occurs in the voltage generation circuit 10 (or 15). Therefore, the voltage generation circuit 10 (or 15) can generate an optimum control voltage in compliance with the characteristic change of the pixel cell 20. Thus, the saturated signal is prevented from being deteriorated by variance in various production parameters and temperature changes.

As described above, according to the present invention, an optimum read voltage can be generated in compliance with a characteristic change of each pixel cell caused by variance in various production parameters and temperature changes, and such an optimum read voltage can be applied to a gate electrode of a signal detection MOS transistor. Therefore, the present invention provides a solid-state imaging device for suppressing the deterioration of the saturated signal caused by the variance in various production parameters and temperature changes and thus providing a high quality image.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state imaging device comprising;
at least one pixel cell for outputting a signal in correspondence with an amount of charges generated by opto-electric conversion; and
a voltage generation circuit for generating a control voltage for outputting the signal from the at least one pixel cell;
wherein a part of the voltage generation circuit has an identical structure to that of a part of the at least one pixel cell.

2. A solid-state imaging device according to claim 1, wherein the at least one pixel cell includes:
a first light receiving diode for generating charges by performing opto-electric conversion of incident light; and
a first signal detection transistor including a charge accumulation region for accumulating charges which are output from the first light receiving diode.

3. A solid-state imaging device according to claim 2, wherein:
the control voltage is applied to the first signal detection transistor for reading the signal; and
the voltage generation circuit includes:
at least one second light receiving diode having an identical structure to that of the first light receiving diode and produced simultaneously with the first light receiving diode; and
at least one second signal detection transistor having an identical structure to that of the first signal detection transistor and produced simultaneously with the first signal detection transistor.

4. A solid-state imaging device according to claim 3, wherein the voltage generation circuit includes:
a first cell and a second cell each including one of the at least one second light receiving diode and one of the at least one second signal detection transistor; and
a differential amplification circuit for receiving an output voltage from each of the first cell and the second cell and thus outputting the control voltage.

5. A solid-state imaging device according to claim 4, wherein:
the second signal detection transistor included in the first cell includes a first source region, a first gate electrode, and a first drain region;
the second signal detection transistor included in the second cell includes a second source region, a second gate electrode, and a second drain region;
for reading the signal, the first source region is connected to one of two inputs of the differential amplification circuit and a first constant current source, the first gate electrode is supplied with a ground voltage, and the first drain region is supplied with a first supply voltage; and
for reading the signal, the second source region is connected to the other of the two inputs of the differential amplification circuit and a second constant current source, the second gate electrode is connected to an output of the differential amplification circuit, and the second drain region is supplied with a second supply voltage.

6. A solid-state imaging device according to claim 4, wherein:
for reading the signal, the first cell is set to a state which is substantially the same as a state where a charge accumulation region included in the first cell is saturated with accumulated charges; and
for reading the signal, the second cell is set to a state which is substantially the same as a state where a charge accumulation region included in the second cell has no charges accumulated therein.

7. A solid-state imaging device according to claim 4, wherein an offset value is added to at least one of the output voltage from the first cell and the output voltage from the second cell.

8. A solid-state imaging device according to claim 5, wherein a current value output by the first constant current source and a current value output by the second constant current source are different from each other.

9. A solid-state imaging device according to claim 5, wherein the at least one pixel cell, the first cell and the second call each act as a source follower circuit for reading the signal.

10. A method for driving a solid-state imaging device, which comprises:
at least one pixel cell for outputting a signal in correspondence with an amount of charges generated by opto-electric conversion; and
a voltage generation circuit for generating a control voltage for outputting the signal from the at least one pixel cell;
wherein:
the at least one pixel cell includes:
a first light receiving diode for generating charges hyperforming opto-electric conversion of incident light; and
a first signal detection transistor including a charge accumulation region for accumulating charges which are output from the first light receiving diode; and
the voltage generation circuit includes:
a first call and a second cell each including a second light receiving diode having an identical structure to that of the first light receiving diode and produced simultaneously with the first light receiving diode, and a second signal detection transistor having an identical structure to that of the first signal detection transistor and produced simultaneously with the first signal detection transistor; and
a differential amplification circuit for receiving an output voltage from each of the first cell and the second cell and thus outputting the control voltage;
the method comprising the step of, for reading the signal, applying a voltage having the same level as that of the voltage applied to a gate electrode included in a non-selected first signal detection transistor to a gate electrode included in the second signal detection transistor of the first call.

11. A method according to claim 10, further comprising the steps of:
before reading the signal, sweeping out charges accumulated in a charge accumulation region included in the second cell, thereby setting the second cell to a state which is substantially the same as a state where the charge accumulation region included in the second cell has no charges accumulated therein; and
before reading the signal, refraining from sweeping out charges accumulated in a charge accumulation region included in the first cell, thereby setting the first cell to a state which is substantially the same as a state where the charge accumulation region included in the first cell is saturated with accumulated charges.

12. A method according to claim 10, further comprising the steps of:
before reading the signal, sweeping out charges accumulated in a charge accumulation region included in the second cell, thereby setting the second cell to a state which is substantially the same as a state where the charge accumulation region included in the second cell has no charges accumulated therein; and
before reading the signal, refraining from sweeping out charges accumulated in a charge accumulation region included in the first cell, and injecting charges into the charge accumulation region included in the first cell, thereby setting the first cell to a state which is substantially the same as a state where the charge accumulation region included in the first cell is saturated with accumulated charges.

13. A method according to claim 10, further comprising the stop of, for reading the signal, applying the control voltage to a gate electrode included in the first signal detection transistor.
